(19) United States
(12) Patent Application Publication
(10) Pub. No.: US 2007/0264747 A1
(43) Pub. Date: Nov. 15, 2007

(54) PATTERNING PROCESS AND METHOD OF MANUFACTURING ORGANIC THIN FILM TRANSISTOR USING THE SAME

(76) Inventors: Kuo-Hsi Yen, Changhua County (TW); Cheng-Wei Chou, Tainan County (TW); Hsiao-Wen Zan, Hsinchu County (TW); Chuan-Yi Wu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,845

(22) Filed: May 15, 2006

(51) Int. Cl. H01L 51/40

(52) U.S. Cl. 438/99

(57) ABSTRACT

A patterning process is provided. The patterning process includes the following steps. First, a substrate is provided. Then, a patterned self-assembled monolayer (SAM) is formed on the substrate. Afterwards, an organic material layer is formed over the substrate to cover the self-assembled monolayer. Thereafter, a portion of the organic material layer is removed, wherein the organic material layer in contact with the patterned SAM is retained such that a patterned organic material layer.

### BACKGROUND OF THE INVENTION

1. Field of the Invention

The present invention relates to a patterning process and a method of manufacturing an organic thin film transistor using the same. More particularly, the present invention relates to a patterning process using a self-assembled monolayer (SAM) and a method of manufacturing an organic thin film transistor (O-TFT) using the patterning process.

2. Description of Related Art

Because organic semiconductor devices can be fabricated on a flexible plastics substrate or a thin metal substrate, it has the advantages of being light, cheap and flexible. Among the organic semiconductor devices, organic thin film transistor (O-TFT) has become one of the most important devices both in the academic circle and among industrial researchers in technically advanced countries.

FIGS. 1A through 1F are schematic cross-sectional views showing the steps of fabricating a conventional organic thin film transistor. First, as shown in FIG. 1A, a gate 120 is formed on a substrate 110. Then, as shown in FIG. 1B, a dielectric layer 130 is formed over the substrate 110 to cover the gate 120. As shown in FIG. 1C, an organic material layer 140 is formed on the dielectric layer 130. The organic material layer 140 subsequently serves as an organic semiconductor layer of the organic thin film transistor 100. Thereafter, as shown in FIG. 1D, a patterned photoresist layer 150 is formed over the organic material layer 140. Then, the organic material layer 140 is patterned in an etching process 160 to form an organic semiconductor layer 170 as shown in FIG. 1E. After that, as shown in FIG. 1F, a source 180a and a drain 180b are formed on the organic semiconductor layer 170. Up to this stage, an organic thin film transistor 100 comprising the gate 120, the organic semiconductor layer 170, the source 180a and the drain 180b of the organic thin film transistor 100 is completely formed.

In the foregoing method of fabricating the organic thin film transistor 100, the interface characteristic between the organic semiconductor layer 170 and the dielectric layer 130 is regarded as poor due to an inorganic material is used for the dielectric layer 130. In addition, as shown in FIG. 1D, the patterned photoresist 150 and the organic material layer 140 are both fabricated using organic material so that their bonding strength is high. Therefore, in the process of removing the patterned photoresist 150 after performing the etching process 160, parts of the organic semiconductor layer 170 may peel off along with the patterned photoresist 150 so that the organic semiconductor layer 170 will have an uneven surface as shown in FIG. 1E. Moreover, the organic semiconductor layer 170 may peel off from the dielectric layer 130 resulting in a drop in the production yield of the organic thin film transistor 100.

Furthermore, using the patterned photoresist 150 as a mask to pattern the organic material layer 140 in the etching process 160 may create additional problems. More specifically, because the patterned photoresist 150 is used as a mask to remove the unprotected organic material layer 140, the pattern in an active region (that is, the organic semiconductor layer 170) having a very high precision is difficult to obtained, such that the performance of the organic thin film transistor 100 may drop and the leakage current in the active region may be excessively large.

### SUMMARY OF THE INVENTION

Accordingly, at least one objective of the present invention is to provide a patterning process capable of defining a pattern with a greater pattern precision.

At least another objective of the present invention is to provide a method of manufacturing an organic thin film transistor capable of improving interface characteristic of an organic semiconductor layer in an active region and defining an organic thin film channel layer with a greater pattern precision.

To achieve these and other advantages and in accordance with the purpose of the invention, as embodied and broadly described herein, the invention provides a patterning process comprising the following steps. First, a substrate is provided. Then, a patterned self-assembled monolayer (SAM) is formed on the substrate. Afterwards, an organic material layer is formed over the substrate to cover the self-assembled monolayer. Thereafter, a portion of the organic material layer is removed, wherein the organic material layer in contact with the patterned SAM is retained such that a patterned organic material layer is formed.

In one embodiment of the present invention, the method of forming the SAM includes the following steps. First, a self-assembled monolayer is formed over the substrate. Then, a photomask is provided. An exposure process to the self-aligned monolayer is carried out using the photomask. Afterwards, the self-aligned monolayer is developed.

In one embodiment of the present embodiment, the light used in the foregoing exposure process includes ultraviolet light.

In one embodiment of the present invention, the foregoing exposure process with ultraviolet light is carried out for a duration between 200˜300 seconds.

In one embodiment of the present invention, the method of removing a portion of the organic material layer includes the following steps. First, a solvent is provided. Then, the solvent is used to clean the substrate.

In one embodiment of the present invention, the foregoing solvent includes water or an organic solvent.

In one embodiment of the present invention, the material of the foregoing patterned self-assembled monolayer is selected from a group consisting of octadecyltriethoxysilane (ODS), octadecyltrichlorosilane (OTS), 1,1,1,3,3,3-hexamethyidisilazane (HMDS) and a combination thereof.

In one embodiment of the present invention, the material of the foregoing organic material layer include pentacene.

In one embodiment of the present invention, the method of forming an organic material layer over the substrate includes a coating or an evaporation process.

The present invention also provides a method of manufacturing an organic thin film transistor. The method includes forming a gate, a dielectric layer, an organic semiconductor layer and a source/drain, characterized in that forming a patterned self-assembled monolayer before the organic semiconductor layer is formed.

In one embodiment of the present invention, the method of forming the SAM includes the following steps. First, a self-assembled monolayer is formed on the dielectric layer. Then, a photomask is provided. An exposure process to the self-aligned monolayer is carried out using the photomask. Afterwards, the self-aligned monolayer is developed.

In one embodiment of the present embodiment, the light used in the foregoing exposure process includes ultraviolet light.

In one embodiment of the present invention, the foregoing exposure process with ultraviolet light is carried out for a duration between 200˜300 seconds.

In one embodiment of the present invention, the organic semiconductor layer covers the patterned self-assembled monolayer. Furthermore, the organic semiconductor layer in contact with the patterned self-assembled monolayer is retained such that a patterned organic semiconductor layer is formed after removing a portion of the organic semiconductor layer.

In one embodiment of the present invention, the method of removing a portion of the organic material layer includes the following steps. First, a solvent is provided. Then, the solvent is used to clean the substrate.

In one embodiment of the present invention, the foregoing solvent includes water or an organic solvent.

In one embodiment of the present invention, the material of the foregoing patterned self-assembled monolayer is selected from a group consisting of octadecyltriethoxysilane (ODS), octadecyltrichlorosilane (OTS), 1,1,1,3,3,3-hexamethyidisilazane (HMDS) and a combination thereof.

In one embodiment of the present invention, the material of the foregoing organic material layer include pentacene.

In one embodiment of the present invention, the method of forming an organic material layer over the substrate includes a coating or an evaporation process.

In one embodiment of the present invention, the gate is formed under the source/drain.

In one embodiment of the present invention, the gate is formed above the source/drain.

The patterning process in the present invention uses a patterned self-assembled monolayer to define the organic semiconductor layer. Therefore, the device can be defined with a greater pattern precision and the interface characteristic of the organic semiconductor layer can be improved. Furthermore, using the patterning process of the present invention to manufacture the organic thin film transistor also improves the interface characteristic of the organic semiconductor layer within the active region and defines the organic semiconductor layer with a greater pattern precision.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing the steps for fabricating a conventional organic thin film transistor.

FIGS. 2A through 2G are schematic cross-sectional views showing the steps in a patterning process according to one preferred embodiment of the present invention.

FIG. 3 is a schematic cross-sectional view of an organic thin film transistor according to one preferred embodiment of the present invention.

FIGS. 4A through 4G are schematic cross-sectional views showing the steps for manufacturing the organic thin film transistor shown in FIG. 3.

FIG. 5 is a schematic cross-sectional view of another organic thin film transistor according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The patterning process and the method of forming the organic thin film transistor in the present invention utilizes a self-assembled monolayer to define an organic material layer with a greater pattern precision. Furthermore, the interface characteristic of the organic material layer is also improved through the self-assembled monolayer. The following illustrations are just some of the preferred embodiments of the present invention and should not be used to limit the scope of the present invention.

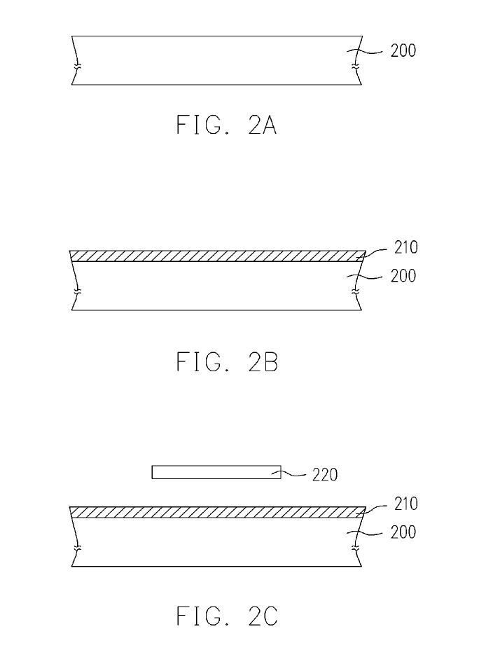

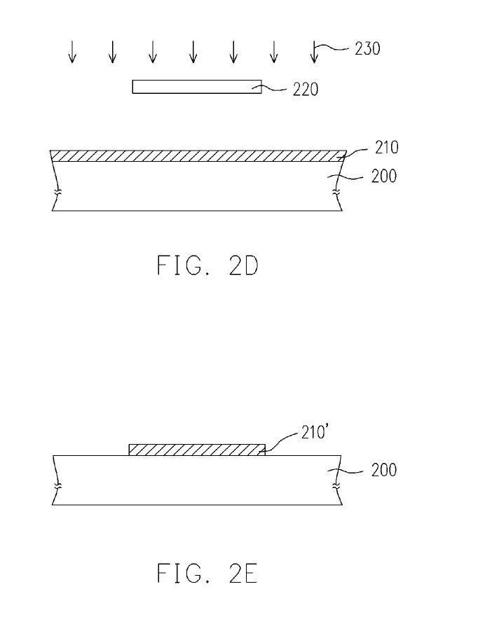

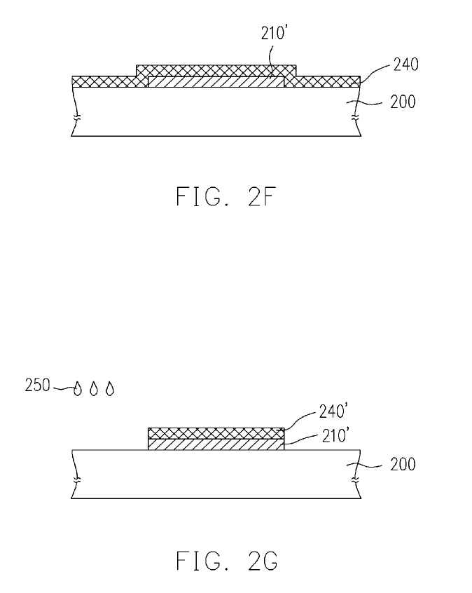

FIGS. 2A through 2G are schematic cross-sectional views showing the steps in a patterning process according to one preferred embodiment of the present invention. First, as shown in FIG. 2A, a substrate 200 is provided. In one embodiment, the substrate 200 can be a flexible plastic substrate having a barrier layer thereon, a metal foil substrate, a silicon substrate or a glass substrate.

Then, a patterned self-assembled monolayer (SAM) 210′ is formed on the substrate 200 (as shown in FIG. 2E). In one embodiment, the method of forming the patterned SAM 210′ includes, for example, performing the steps from 2B to 2E. First, as shown in FIG. 2B, a self-assembled monolayer 210 is formed on a substrate 200. The self-assembled monolayer 210 is formed, for example, by performing a coating process or an evaporation process. Furthermore, the material constituting the self-assembled monolayer 210 is selected from a group consisting of octadecyltriethoxysilane (ODS), octadecyltrichlorosilane (OTS), 1,1,1,3,3,3-hexamethyidisilazane (HMDS) and a combination thereof.

As shown in FIG. 2C, a photomask 220 is provided. In one embodiment, the photomask 220 has a device pattern (not shown) that will be transferred to the self-assemble monolayer 210.

As shown in FIG. 2D, an exposure process 230 to the self-assembled monolayer 210 is carried out using the photomask 220. In one embodiment, the light used in the exposure process 230 is ultraviolet light. Preferably, the ultraviolet light used in the exposure process 230 illuminates the self-assembled monolayer 210 for a duration between 200˜300 seconds so that the device pattern can be completely transferred to the self-assembled monolayer 210. In particular, if the self-assembled monolayer 210 is fabricated using ODS, it absorbs ultraviolet light strongly. Therefore, the device pattern on the photomask 220 can be accurately transferred to the self-assembled monolayer 210 such that an increased pattern precision can be obtained.

As shown in FIG. 2E, the exposed self-assembled monolayer 210 is developed. Up to this stage, the fabrication of the patterned self-assembled monolayer 210′ is complete. Particularly, because the self-assembled monolayer 210 will dissociate after illuminating with ultraviolet light, the ultraviolet light illuminated self-assembled monolayer 210 can be removed after performing a development process. The self-assembled monolayer 210 can be developed out using any conventional development process in semiconductor production. For example, a soft organic solvent can be used to remove the dissociated self-assembled monolayer 210 after illuminating with ultraviolet light, whose details are not elaborated here.

As shown in FIG. 2F, an organic material layer 240 is formed over the substrate 200. The organic material layer 240 also covers the patterned self-assembled monolayer 210′. In one embodiment, the organic material layer 240 is fabricated using pentacene. Furthermore, the method of forming the organic material layer 240 over the substrate 200 includes performing a coating process or an evaporation process.

As shown in FIG. 2G, a portion of the organic material layer 240 is removed. The organic material layer 240 in contact with the patterned self-assembled monolayer 201′ is retained such that a patterned organic material layer 240′ is formed. In one embodiment, the method of removing a portion of the organic material layer 240 includes the following steps. First, a solvent 250 is provided. The solvent is, for example, water or an organic solvent. Then, the solvent 250 is used to clean the substrate 200. Because the bonding strength between the organic material layer 240 and the patterned self-assembled monolayer 210′ is stronger than the bonding strength between the organic material layer 240 and the solvent 250, a patterned organic material layer 240′ is naturally formed on the patterned self-assembled monolayer 210′ after the organic material layer 240 is cleaned using the solvent 250.

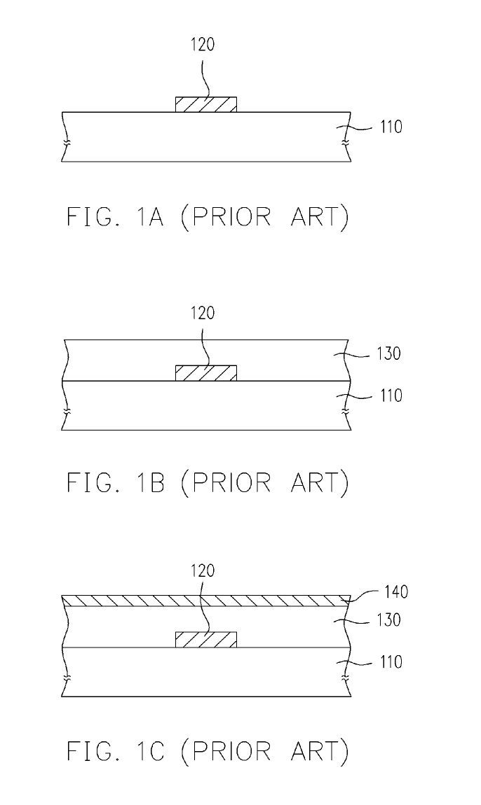

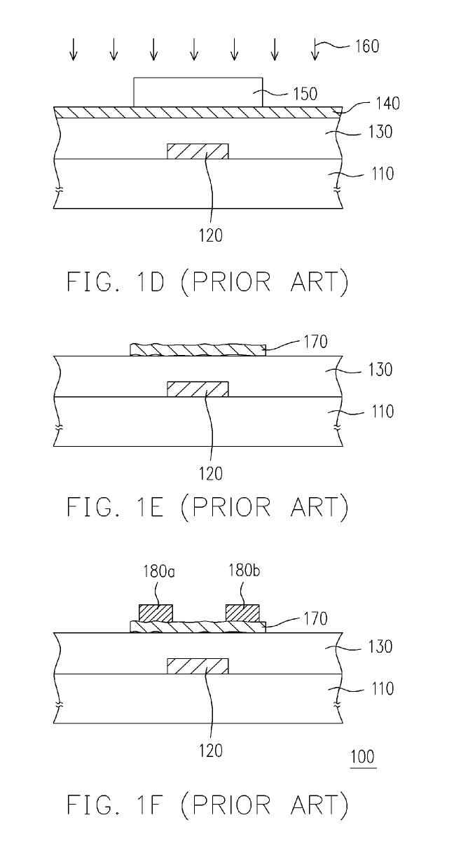

It should be noted that the patterning process in the present invention does not require the patterned photoresist 150 (as shown in FIG. 1D) to pattern the organic material layer 240. Hence, the present invention does not have the associated problem of organic semiconductor layer 170 peeling away when the patterned photoresist 150 is removed in the conventional process leading to a drop in pattern precision.

Furthermore, the present invention utilizes a self-assembled monolayer 210 with strong absorption capacity for ultraviolet light so that the device pattern on the photomask 220 can be directly transferred to the self-assembled monolayer 210. Therefore, the patterned self-assembled monolayer 210′ has a greater pattern precision so that the organic material layer 240 can be more precisely defined. Moreover, the self-assembled monolayer 210 is located between the organic material layer 240 and the substrate 200. As a result, the interface characteristic of the organic material layer 240 is significantly improved.

In addition, due to the significantly larger bonding strength between the organic material layer 240 and the patterned self-assembled monolayer 210′ relative to the bonding strength between the organic material layer 240 and the substrate 200, the organic material layer 240 not in contact with the patterned self-assembled monolayer 210′ can be easily removed using the solvent 250. Thus, the fabrication process is simplified and the throughput of the patterning process is increased.

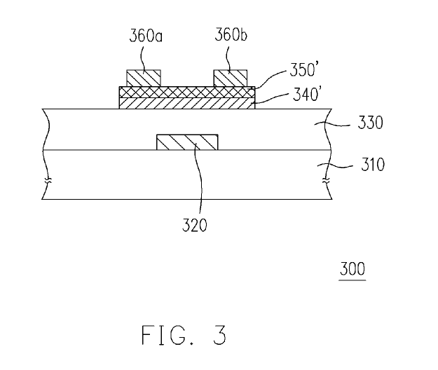

The foregoing patterning process provides an effective method of defining the active region of an organic thin film transistor. FIG. 3 is a schematic cross-sectional view of an organic thin film transistor according to one preferred embodiment of the present invention. As shown in FIG. 3, the method of fabricating the organic thin film transistor 300 in the present invention includes forming a gate 320, a dielectric layer 330, an organic semiconductor layer 350′, a source 360a and a drain 360b. In particular, a patterned self-assembled monolayer 340′ is formed before an organic semiconductor layer 350′ is formed. In the following, a method of fabricating an organic thin film transistor is described using the organic thin film transistor 300 in FIG. 3 as an example. However, the following description is used as an example only and should not be used to limit the organic thin film transistor structure fabricated by the method in the present invention.

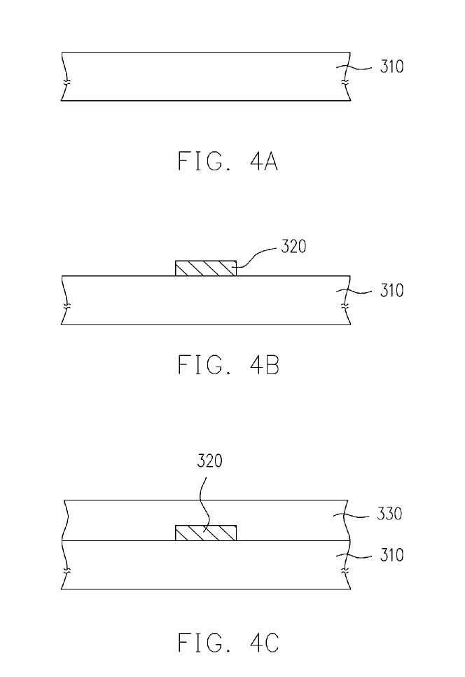

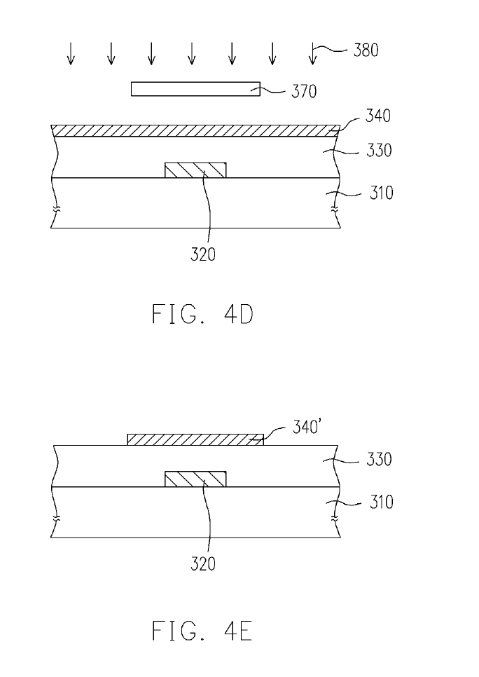

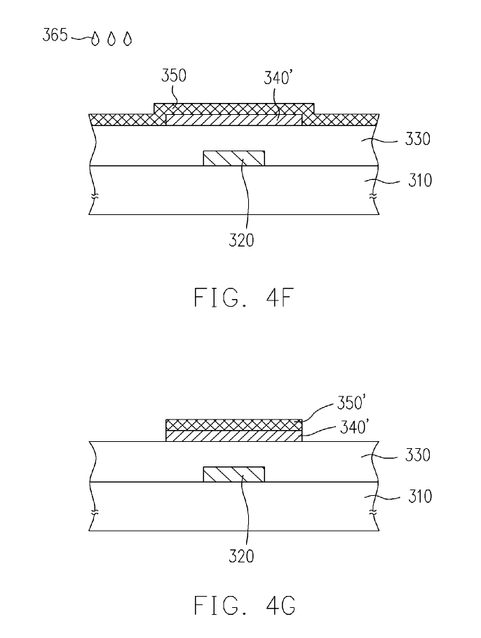

FIGS. 4A through 4G are schematic cross-sectional views showing the steps for manufacturing the organic thin film transistor shown in FIG. 3. As shown in FIG. 4A, a substrate 310 is provided. In one embodiment, the substrate 310 can be a flexible plastic substrate having a barrier layer thereon, a metal foil substrate, a silicon substrate or a glass substrate.

As shown in FIG. 4B, a gate 320 is formed on the substrate 310. In one embodiment, the gate 320 is formed performing a conventional thin film deposition process together with a photolithographic/etching process. Alternatively, the gate 320 is formed by performing a thin film deposition process with a shadow mask.

As shown in FIG. 4C, a dielectric layer 330 is formed over the substrate 310 to cover the gate 320. In one embodiment, the method of forming the dielectric layer 330 includes performing a chemical vapor deposition (CVD) process or some other suitable methods. The dielectric layer 330 is fabricated using, for example, silicon oxide, silicon nitride or organic dielectric materials such as Poly(methyl methacrylate) (PMMA) and hydrogen silsesquioxane (HSQ).

Thereafter, a patterned self-assembled monolayer 340′ (as shown in FIG. 4E) is formed on the dielectric layer 330. In one embodiment, the method of forming the patterned self-assembled monolayer 340′ includes the steps shown in FIGS. 4D˜4E. First, as shown in FIG. 4D, a self-assembled monolayer 340 is formed on the dielectric layer 330. In one embodiment, the method of forming the self-assembled monolayer 340 includes performing a coating process or an evaporation process. Furthermore, the material constituting the self-assembled monolayer 340 is selected from a group consisting of octadecyltriethoxysilane (ODS), octadecyltrichlorosilane (OTS), 1,1,1,3,3,3-hexamethyidisilazane (HMDS) and a combination thereof.

As shown in FIG. 4D, a photomask 370 is provided. The photomask 370 has a device pattern that can be transferred to the self-assembled monolayer 340. Then, an exposure process 380 to the self-assembled monolayer 340 is carried out using the photomask 370. After that, the exposed self-assembled monolayer 340 is developed to form the patterned self-assembled monolayer 340′ as shown in FIG. 4E. In one embodiment, the light used in the exposure 380 is ultraviolet light. Preferably, the ultraviolet light used in the exposure 380 illuminates the self-assembled monolayer 340 for a duration between 200˜300 seconds so that the device pattern can be completely transferred to the self-assembled monolayer 340. In particular, if the self-assembled monolayer 340 is fabricated using ODS, it absorbs ultraviolet light strongly. Therefore, the device pattern on the photomask 370 can be accurately transferred to the self-assembled monolayer 340 such that an increased pattern precision can be obtained.

As shown in FIGS. 4F˜4G, a patterned organic semiconductor layer 350′ is formed on the patterned self-assembled monolayer 340′. First, as shown in FIG. 4F, an organic semiconductor layer 350 is globally formed on the substrate 310. In one embodiment, the method of forming the organic semiconductor layer 350 includes performing a coating process or an evaporation process. The organic semiconductor layer 350 is fabricated using, for example, pentacene. As shown in FIG. 4F and FIG. 4G, the organic semiconductor layer 350 covers the patterned self-assembled monolayer 340′. Furthermore, as a portion of the organic semiconductor layer 350 is removed, and the organic semiconductor layer 350 in contact with the patterned self-assembled monolayer 340′ is retained such that the patterned organic semiconductor layer 350′ is formed.

More specifically, the foregoing method of removing a portion of the organic semiconductor layer 350 includes the following steps. First, a solvent 365 is provided as shown in FIG. 4F. Then, the substrate 310 is cleaned using the solvent 365. In one embodiment, the solvent 365 includes water or an organic solvent. Because the bonding strength between the organic semiconductor layer 350 and the patterned self-assembled monolayer 340′ is greater than the bonding strength between the organic semiconductor layer 350 and the solvent 365, a patterned organic material layer 350′ is naturally formed on the patterned self-assembled monolayer 340′ after the organic material layer 350 is cleaned using the solvent 365 as shown in FIG. 4F to FIG. 4G.

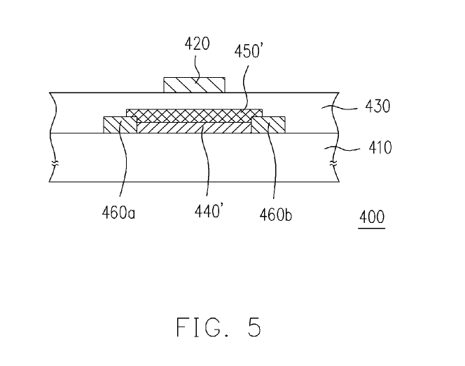

Finally, a source 360a and a drain 360b are fabricated on the patterned organic semiconductor layer 350 to obtain the organic thin film transistor 300 as shown in FIG. 3. It should be noted that the gate 320 is formed under the source 360a/drain 360b. Hence, it is called a bottom-gate organic thin film transistor. However, in other embodiment, the foregoing method can be used to form a top-gate organic thin film transistor 400 as shown in FIG. 5. As shown in FIG. 5, a gate 420, a dielectric layer 430, an organic semiconductor layer 450′ and a source 460a/drain 460b are formed on a substrate 410. In the present embodiment, the gate 420 is formed above the source 460a/drain 460b. Because the method of fabricating the top-gate organic thin film transistor 400 is similar to forming the organic thin film transistor 300 in FIG. 3, a detailed description is not repeated here. It should be noted that the patterned self-assembled monolayer 440′ is formed before the organic semiconductor layer 450′ in fabricating the organic thin film transistor 400 shown in FIG. 5. Through the patterned self-assembled monolayer 440′, the active region of the organic thin film transistor 400 is defined with a greater pattern precision and the interface characteristic of the organic semiconductor layer 450′ is improved.

Furthermore, the methods of using patterned self-assembled monolayers 340′, 440′ to define the respective organic semiconductor layers 350′, 450′ are not limited to the fabrication of the two foregoing organic thin film transistors 300, 400. The methods can also be applied to fabricate an organic thin film transistor having other structures so that the selectivity ratio of the active layer deposition in the active region of the organic thin film transistor is increased and the interface characteristic of the active layer is improved.

In summary, the patterning process and the method of forming the organic thin film transistor in the present invention has the following advantages:

1. The patterning process is simplified using the self-assembled monolayer. Moreover, the organic semiconductor layer can be defined with a greater pattern precision.

2. With the self-assembled monolayer disposed between the organic material layer and the substrate, the interface characteristic of the organic material layer is improved so that the probability of the organic material layer peeling off from the substrate is substantially reduced.

3. Defining the active region of the organic thin film transistor using the self-assembled monolayer produces an organic semiconductor layer having a greater pattern precision. Therefore, the performance of the organic thin film transistor is improved and leakage current from the active region is reduced.

4. With the self-assembled monolayer disposed between the active region of the organic semiconductor layer and the substrate, the interface characteristic of the organic semiconductor layer is improved and the organic semiconductor layer peeling off form the substrate is prevented. Thus, the production yield of the organic thin film transistor is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A patterning process, comprising:
providing a substrate;
forming a patterned self-assembled monolayer on the substrate;
forming an organic material layer over the substrate to cover the patterned self-assembled monolayer; and
removing a portion of the organic material layer, wherein the organic material layer in contact with the patterned self-assembled monolayer is retained such that a patterned organic material layer is formed.

2. The patterning process of claim 1, wherein the step of forming the patterned self-assembled monolayer comprises:
forming a self-assembled monolayer over the substrate;
providing a photomask;
performing an exposure process to the self-assembled monolayer using the photomask; and
developing the self-assembled monolayer.

3. The patterning process of claim 2, wherein the light source used in the exposure process comprises ultraviolet light.

4. The patterning process of claim 3, wherein the exposure process comprises illuminating with ultraviolet light for a duration between 200˜300 seconds.

5. The patterning process of claim 1, wherein the step of removing a portion of the organic material layer comprises:
providing a solvent; and
cleaning the substrate with the solvent.

6. The patterned process of claim 5, wherein the solvent comprises water or an organic solvent.

7. The patterning process of claim 1, wherein the material of the patterned self-assembled monolayer is selected from a group consisting of octadecyltriethoxysilane (ODS), octadecyltrichlorosilane (OTS), 1,1,1,3,3,3-hexamethyidisilazane (HMDS) and a combination thereof.

8. The patterning process of claim 1, wherein the material of the organic material layer comprises pentacene.

9. The patterning process of claim 1, wherein the step of forming the organic material layer comprises performing a coating process or an evaporation process.

10. A method of manufacturing an organic thin film transistor, the method including forming a gate, a dielectric layer, an organic semiconductor layer and a source/drain, characterized in that:
forming a patterned self-assembled monolayer before the organic semiconductor layer is formed.

11. The method of claim 10, wherein the step of forming the patterned self-assembled monolayer comprises:
forming a self-assembled monolayer on the dielectric layer;
providing a photomask;
performing an exposure process to the self-assembled monolayer using the photomask;
developing the self-assembled monolayer.

12. The method of claim 11, wherein the light source used in the exposure process comprises ultraviolet light.

13. The method of claim 12, wherein the exposure process comprises illuminating with ultraviolet light for a duration between 200˜300 seconds.

14. The method of claim 10, wherein the organic semiconductor layer covers the patterned self-assembled monolayer, and when a portion of the organic semiconductor layer is removed, the organic semiconductor layer in contact with the patterned self-assembled monolayer is retained such that a patterned organic semiconductor layer is formed.

15. The method of claim 14, wherein the step of removing a portion of the organic semiconductor layer comprises:
providing a solvent; and
cleaning the substrate with the solvent.

16. The method of claim 15, wherein the solvent comprises water or an organic solvent.

17. The method of claim 10, wherein the material of the patterned self-assembled monolayer is selected from a group consisting of octadecyltriethoxysilane (ODS), octadecyltrichlorosilane (OTS), 1,1,1,3,3,3-hexamethyidisilazane (HMDS) or a combination of the above.

18. The method of claim 10, wherein the material of the organic material layer comprises pentacene.

19. The method of claim 10, wherein the step of forming the organic material layer on the substrate comprises performing a coating process or an evaporation process.

20. The method of claim 10, wherein the gate is formed under the source/drain.

21. The method of claim 10, wherein the gate is formed over the source/drain.
